(19) United States
(12) Patent Application Publication
(10) Pub. No.: US 2025/0271493 A1
(43) Pub. Date: Aug. 28, 2025

(54) DISPLAY DEVICE CAPABLE OF DETECTING PANEL CRACKS

(71) Applicant: LG Display Co., Ltd., Seoul (KR)

(72) Inventor: Jung Min SEO, Paju-si (KR)

(73) Assignee: LG Display Co., Ltd., Seoul (KR)

(21) Appl. No.: 19/062,628

(22) Filed: Feb. 25, 2025

(30) Foreign Application Priority Data
Feb. 28, 2024 (KR) 10-2024-0028972

(51) Int. Cl. G01R 31/28

(52) U.S. Cl. CPC G01R 31/2825

(57) ABSTRACT

A display device includes a display panel, a loop resistance circuit disposed in an edge region of the display panel, and a crack detection circuit configured to detect a resistance value of the loop resistance circuit, wherein the loop resistance circuit includes first detection regions having different resistance values and second detection regions having different resistance values.

### CROSS-REFERENCE TO RELATED APPLICATIONS

This application claims the benefit of the Korean Patent Application No. 10-2024-0028972 filed on Feb. 28, 2024, which is hereby incorporated by reference as if fully set forth herein.

### BACKGROUND

### Technical Field

The present disclosure relates to a display device capable of detecting panel cracks.

### Description of the Related Art

A method of detecting cracks of a panel in display device has been known. A panel crack detection method of the related art forms a crack detection loop at an outer portion of a panel and determines whether the loop is disconnected, based on a loop voltage difference.

### BRIEF SUMMARY

The panel crack detection method of the related art may merely determine whether there is a crack, based on a disconnection of an entire loop, but have a structural limitation in determining an accurate position of the crack. To overcome the aforementioned problem of the related art, the present disclosure provides a display device which determines a position at which a panel crack occurs, based on a loop resistance circuit and a crack detection circuit.

To achieve these objects and other advantages and in accordance with the purpose of the disclosure, as embodied and broadly described herein, a display device includes a display panel; a loop resistance circuit disposed in an edge region of the display panel; and a crack detection circuit configured to detect a resistance value of the loop resistance circuit, wherein the loop resistance circuit includes first detection regions having different resistance values and second detection regions having different resistance values, the edge region is divided into a first edge region including a right edge region and an upper partial edge region and a second edge region including a left edge region and the other upper edge region, the first detection regions correspond to the first edge region, and the second detection regions correspond to the second edge region.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram illustrating a display device according to an embodiment of the present disclosure;

FIG. 2 is a diagram illustrating an example where pixels included in a display panel is arranged;

FIG. 3 is a diagram illustrating another example where pixels included in a display panel is arranged;

FIG. 4 is a block diagram illustrating a configuration of a drive integrated circuit (IC) illustrated in FIG. 1;

FIG. 5 is a diagram schematically illustrating a pixel circuit of each subpixel;

FIG. 6 is a diagram illustrating an example of a loop resistance circuit provided at an outer portion of a display panel;

FIG. 7 is a diagram illustrating a configuration of a crack detection circuit;

FIG. 8 is a driving waveform diagram for describing an operation of a crack detection circuit;

FIG. 9 is a diagram illustrating another configuration of a loop resistance circuit; and

FIG. 10 is a diagram illustrating another configuration of a loop resistance circuit.

### DETAILED DESCRIPTION

Hereinafter, exemplary embodiments of the present disclosure will be described in detail with reference to the accompanying drawings. In the specification, in adding reference numerals for elements in each drawing, it should be noted that like reference numerals already used to denote like elements in other drawings are used for elements wherever possible. In the following description, when the detailed description of the relevant known function or configuration is determined to unnecessarily obscure the important point of the present disclosure, the detailed description will be omitted.

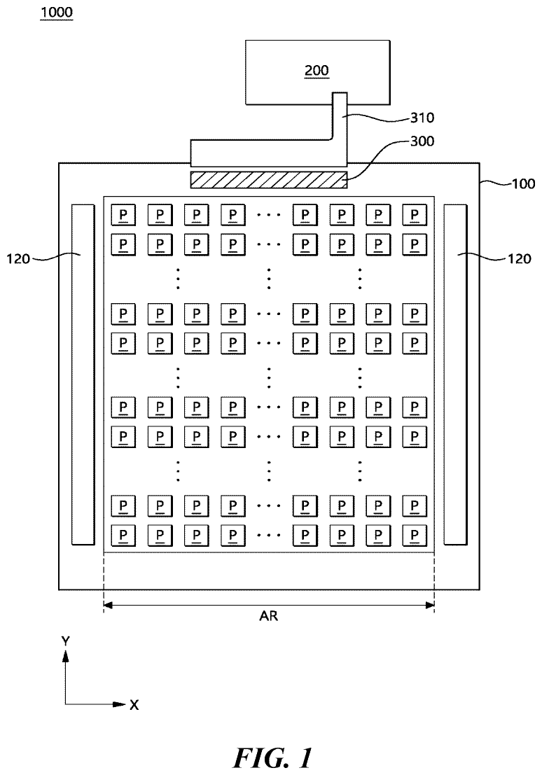

Referring to FIGS. 1 to 4, a display device 1000 according to an embodiment of the present disclosure may be implemented as various types such as electroluminescent display device and liquid crystal display (LCD) device. In the present embodiment, a case where the display device 1000 is implemented as an electroluminescent display device may be described, but the inventive concept is not limited to the electroluminescent display device and may be widely applied to display devices of various types.

The display device 1000 according to an embodiment of the present disclosure may include a display panel 100 and display panel drivers.

The display panel drivers may write input image data in pixels P of a screen AR to display an image on the screen AR. The display panel drivers may include a gate driver 120 which supplies a gate signal to gate lines GL1 and GL2 of the display panel 100, a data driver 306 which converts the image data into a voltage of a data signal (hereinafter referred to as a “data voltage”) to supply data voltages to data lines DL1 to DL6 through data output channels, and a timing controller 303 which controls an operation timing of each of the data driver 306 and the gate driver 120. The data driver 306 and the timing controller 303 may be integrated into a drive integrated circuit (IC) 300.

The screen AR of the display panel 100 may include the data lines DL1 to DL6, the gate lines GL1 and GL2 intersecting with the data lines DL1 to DL6, and a pixel array where pixels P are arranged in a matrix form. The pixels P may be arranged in the pixel array in a matrix form defined by the data lines DL1 to DL6 and the gate lines GL1 and GL2. The pixels P may display an image with data voltages applied thereto.

Each of the pixels P may include a plurality of subpixels for implementing colors. The subpixels may include a red subpixel (herein referred to as an “R subpixel”), a green subpixel (herein referred to as a “G subpixel”), and a blue subpixel (herein referred to as a “B subpixel”). Although not shown, a white subpixel may be further included in the pixel P.

Each of the subpixels may include an internal compensation circuit which senses an electrical characteristic (for example, a threshold voltage) of a driving element to compensate for a gate voltage of the driving element.

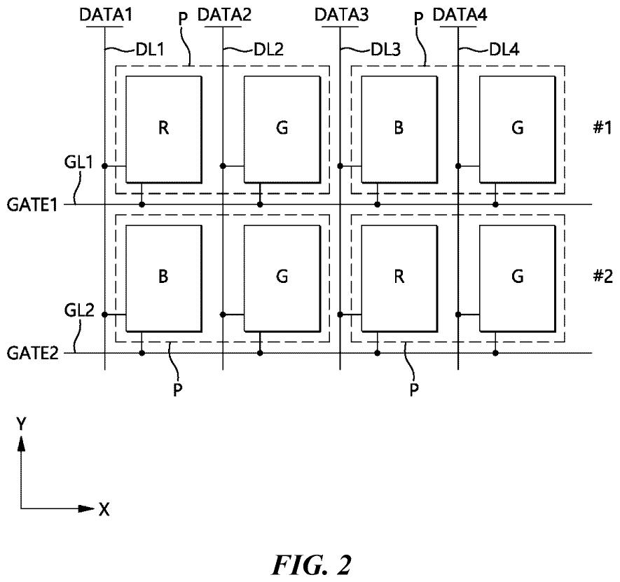

The subpixels may configure a real color pixel P or a pentile pixel P. The pentile pixel P, as illustrated in FIG. 2, may drive two subpixels of different colors as one pixel P to implement a resolution which is higher than that of the real color pixel, based on a predetermined pixel rendering algorithm. The pixel rendering algorithm may compensate for insufficient color expression by using a color of light emitted from an adjacent subpixel in each of the subpixels.

In the real color pixel P, as illustrated in FIG. 3, one pixel P may be configured with R, G, and B subpixels.

When a resolution of the pixel array is n*m, the pixel array may include n number of pixel columns and m number of pixel rows intersecting with the pixel column. In FIGS. 2 and 3, #1 and #2 may each represent a number of a pixel row. The pixel column may include pixels P which are arranged in a Y-axis direction. The pixel row may include pixels P which are arranged in an X-axis direction. One horizontal period 1 H may be a time obtained by dividing one frame period by the number of m pixel rows. The gate driver 120 may sequentially output the gate signal up to an m^{th} pixel row from a first pixel row to perform progressive scan on the pixels P by row units. Each of subpixels of one pixel row may operate in the order of initialization, sensing, and data writing in one horizontal period.

The pixel array of the display panel 100 may be formed on a glass substrate, a metal substrate, or a plastic substrate. In a plastic panel, the pixel array may be formed on the plastic substrate, and thus, the display panel 100 may be implemented as a flexible panel. The plastic panel may include the pixel array on an organic thin film attached on a back plate. A touch sensor array may be formed on the pixel array.

The back plate may be a polyethylene terephthalate (PET) substrate. The organic thin film may be formed on the back plate. The pixel array and the touch sensor array may be formed on the organic thin film. The back plate may prevent the penetration of water into the organic thin film so that the pixel array is not exposed to water. The organic thin film may be a thin polyimide (PI) film substrate. A multi-layer buffer layer may be formed of an insulating material (not shown) on the organic thin film. Lines for supplying power or a signal applied to the pixel array and the touch sensor array may be formed on the organic thin film.

The gate driver 120 and the pixel array may be mounted on the substrate of the display panel 100. The gate driver 120 directly formed on the substrate of the display panel 100 has been known as a gate in panel (GIP) circuit.

The gate driver 120 may be disposed in one of a left bezel and a right bezel of the display panel 100 and may supply the gate signal to the gate lines GL1 and GL2, based on a single feeding method. In the single feeding method, in FIG. 1, one of two gate drivers 120 may not be needed.

The gate driver 120 may be disposed in each of the left bezel and the right bezel of the display panel 100 and may supply the gate signal to the gate lines GL1 and GL2, based on a double feeding method. In the double feeding method, the gate signal may be simultaneously applied to both ends of one gate line.

The gate driver 120 may be driven based on a gate timing signal supplied from the drive IC 300 and may supply gate signals GATE1 and GATE2 to the gate lines GL1 and GL2 by using a shift register. The shift register may shift the gate signals GATE1 and GATE2, and thus, may sequentially supply the gate signals GATE1 and GATE2 to the gate lines GL1 and GL2. The gate signals GATE1 and GATE2 may include a scan signal and an emission control signal.

The drive IC 300 may output a gate timing signal for controlling the gate driver 120. The drive IC 300 may be connected to the data lines DL1 to DL6 through the data output channels and may supply data voltages to the data lines DL1 to DL6.

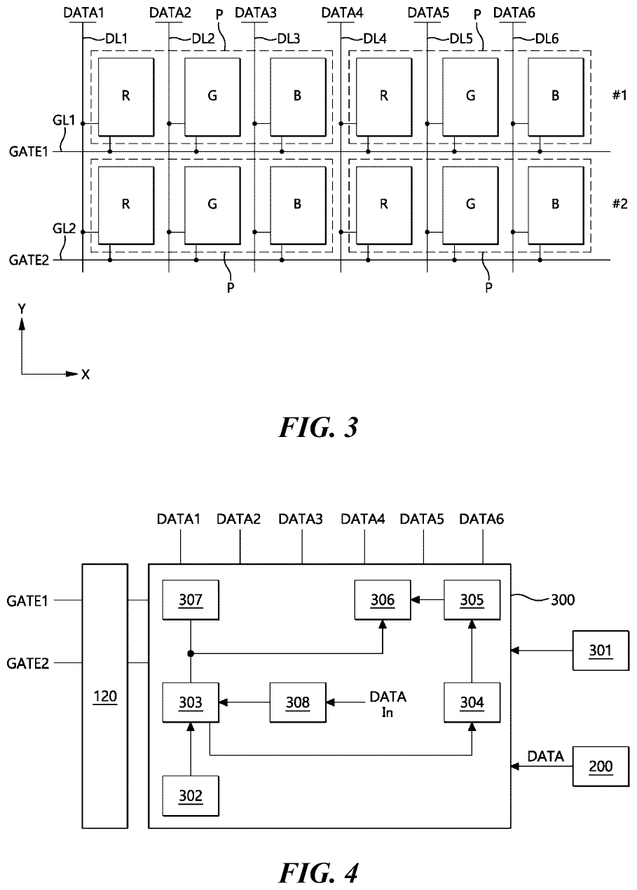

The drive IC 300, as illustrated in FIG. 4, may be connected to a host system 200, a first memory 301, and the gate driver 120. The drive IC 300 may include a data calculator 308, the timing controller 303, and the data driver 306. The drive IC 300 may further include a second memory 302, a gamma compensation voltage generator 305, a power unit 304, and a level shifter 307.

The timing controller 303 may supply image data DATA, received from the host system 200, to the data driver 306. The timing controller 303 may generate the gate timing signal for controlling the gate driver 120 and a source timing signal for controlling the data driver 306 to control an operation timing of each of the gate driver 120 and the data driver 306.

The level shifter 307 may receive gate timing signals from the timing controller 303 to shift voltage levels of the gate timing signals. The gate timing signal may include a gate timing signal such as a start pulse VST and a shift clock GCLK and a gate voltage such as a gate on voltage VGL and a gate off voltage VGH. The start pulse VST and the shift clock GCLK may swing between the gate on voltage VGL and the gate off voltage VGH.

The level shifter 307 may shift a low-level voltage of the gate timing signal, received from the timing controller 303, to the gate on voltage VGL and may shift a high-level voltage of the gate timing signal to the gate off voltage VGH. The level shifter 307 may output the gate timing signal and the gate voltages VGH and VGL to supply to the gate driver 120 through output channels.

The data calculator 308 may receive the image data DATA from the host system 200 and may modulate the received image data DATA by using a predetermined image quality algorithm, thereby enhancing image quality. The data calculator 308 may include a data recover unit which decodes compressed image data DATA to recover image data and an optical compensator which adds a predetermined optical compensation value to the image data DATA. The optical compensation value may be set to a value for correcting luminance of each image data, based on luminance of a screen measured based on a camera image captured in a manufacturing process.

The data driver 306 may convert image data (a digital signal) received from the timing controller 303 with a gamma compensation voltage to output data voltages by using a digital-to-analog converter (DAC). The data voltages output from the data driver 306 may be supplied to the data lines DL1 to DL6 of the pixel array through an output buffer connected to a data channel of the drive IC 300.

The gamma compensation voltage generator 305 may divide a gamma reference voltage from the power unit 304 by using a voltage division circuit to generate a grayscale-based gamma compensation voltage. The gamma compensation voltage may be an analog voltage where a voltage is set for each gray level of image data. The gamma compensation voltage output from the gamma compensation voltage generator 305 may be supplied to the data driver 306.

The power unit 304 may generate power needed for driving of the pixel array of the display panel 100, the gate driver 120, and the drive IC 300 by using DC-DC converter. The DC-DC converter may include a charge pump, a regulator, a buck converter, and a boost converter. The power unit 304 may adjust a direct current (DC) input voltage from the host system 200 to generate a DC power such as the gamma reference voltage, the gate on voltage, the gate off voltage, a pixel driving voltage, a low-level source voltage, and an initialization voltage.

The gamma reference voltage may be supplied to the gamma compensation voltage generator 305. The gate on voltage and the gate off voltage may be supplied to the level shifter 307 and the gate driver 120. A pixel power such as the pixel driving voltage, the low-level source voltage, and the initialization voltage may be supplied to the subpixels in common. Each of the subpixels may configure a pixel circuit including a light emitting device and a driving element.

The initialization voltage may be a voltage which initializes main nodes of the pixel circuit. The initialization voltage may be set to a DC voltage which is lower than a lowest data voltage and is lower than a threshold voltage of the light emitting device, may prevent the light emitting device from emitting light, and may initialize the main nodes of the pixel circuit.

The second memory 302 may store a compensation value and a register setting value received from the first memory 301 when power is input to the drive IC 300. The compensation value may be applied to various algorithms for enhancing image quality. The compensation value may include an optical compensation value.

The register setting value may define an output voltage level of the power unit 34 and timings of waveforms and operations of the data driver 306, the timing controller 303, the gamma compensation voltage generator 305, and the power unit 34. The first memory 301 may include flash memory. The second memory 302 may include static random access memory (SRAM).

The host system 200 may be one of a television (TV) system, a set-top box, a navigation system, a personal computer (PC), a home theater system, a mobile device, and a wearable device.

The host system 200 in the mobile system may be implemented as an application processor. The host system 200 in the mobile system may transfer input image data to the drive IC 300 through a mobile industry processor interface (MIPI). The host system 200 may be connected to, for example, the drive IC 300 through a flexible printed circuit (FPC) 310.

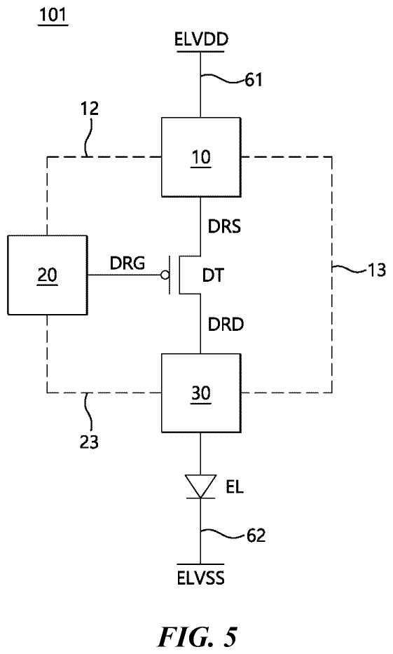

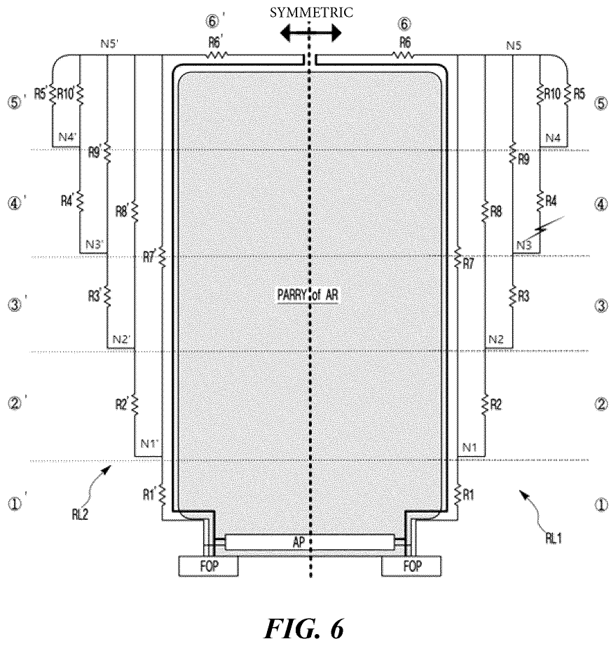

FIG. 5 is a diagram schematically illustrating a pixel circuit 101 of each subpixel.

Referring to FIG. 5, the pixel circuit 101 may include first to third circuit units 10, 20, and 30 and first to third connection units 12, 23, and 13. One or more elements may be omitted in or added to the pixel circuit 101.

The first circuit unit 10 may be connected to a pixel driving voltage ELVDD through a first power line 61 and may supply the pixel driving voltage ELVDD to a driving element DT. The driving element DT may be implemented as a transistor including a gate DRG, a source DRS, and a drain DRD. The second circuit unit 20 may charge a capacitor connected to the gate DRG of the driving element DT and may hold a voltage of the capacitor during one frame period. The third circuit unit 30 may supply a light emitting device EL with a current supplied from the pixel driving voltage ELVDD through the driving element DT, and thus, the current may be converted into light. The light emitting device EL may be connected to a low-level source voltage ELVSS through a second power line 62. The low-level source voltage ELVSS may be supplied to a cathode electrode of the light emitting device EL.

The first to third circuit units 10, 20, and 30 may include an internal compensation circuit for compensating for a threshold voltage of the driving element DT. The third circuit unit 30 may be connected to a sensing unit which senses the threshold voltage or electrical characteristic variation of the driving element DT. The sensing unit may be mounted on a drive IC outside a panel.

The first connection unit 12 may connect the first circuit unit 10 to the second circuit unit 20. The second connection unit 23 may connect the second circuit unit 20 to the third circuit unit 30. The third connection unit 13 may connect the third circuit unit 30 to the first circuit unit 10. Each of the first connection unit 12, the second connection unit 23, and the third connection unit 13 may include one or more transistors and lines.

FIG. 6 is a diagram illustrating an example of a loop resistance circuit provided at an outer portion of a display panel.

Referring to FIG. 6, a display device according to an embodiment of the present disclosure may include a plurality of loop resistance circuits RL1 and RL2 which are disposed in a non-display area (hereinafter referred to as an edge region) outside a pixel array PARRAY configuring a screen AR in a display panel and a crack detection circuit AP for detecting resistance values of the loop resistance circuits RL1 and RL2.

To determine a position at which a panel crack occurs, the loop resistance circuits RL1 and RL2 may be divided into first detection regions RL1 having different resistance values and second detection regions RL2 having different resistance values.

The first detection regions RL1 may correspond to a first edge region of the display panel. The first edge region may include a right edge region and an upper partial edge region of the display panel.

The first detection regions RL1 may include a plurality of first resistors R1 to R6 and first resistance lines.

The plurality of first resistors R1 to R6 may have different resistance values and may be connected to each other through the first resistance lines.

The resistor R1 may correspond to a detection region \textcircled{1}, the resistor R2 may correspond to a detection region \textcircled{2}, the resistor R3 may correspond to a detection region \textcircled{3}, the resistor R4 may correspond to a detection region \textcircled{4}, the resistor R5 may correspond to a detection region \textcircled{5}, and the resistor R6 may correspond to a detection region \textcircled{6}.

The resistor R1 may be connected to an FPCB on panel (FOP) and a first branch node N1, the resistor R2 may be connected to the first branch node N1 and a second branch node N2, the resistor R3 may be connected to the second branch node N2 and a third branch node N3, the resistor R4 may be connected to the third branch node N3 and a fourth branch node N4, the resistor R5 may be connected to the fourth branch node N4 and a fifth branch node N5, and the resistor R6 may be connected to the fifth branch node N5 and the crack detection circuit AP.

To determine an accurate position of a panel crack, the first detection regions RL1 may further include a resistor R7 connected between the first branch node N1 and the fifth branch node N5, a resistor R8 connected between the second branch node N2 and the fifth branch node N5, a resistor R9 connected between the third branch node N3 and the fifth branch node N5, and a resistor R10 connected between the fourth branch node N4 and the fifth branch node N5.

The second detection regions RL2 may correspond to a second edge region of the display panel. The second edge region may include a left edge region and the other upper edge region of the display panel.

The second detection regions RL2 may include a plurality of second resistors R1′ to R6′ and second resistance lines.

The plurality of second resistors R1′ to R6′ may have different resistance values and may be connected to each other through the second resistance lines.

The resistor R1′ may correspond to a detection region \textcircled{1}′, the resistor R2′ may correspond to a detection region \textcircled{2}′, the resistor R3′ may correspond to a detection region \textcircled{3}′, the resistor R4′ may correspond to a detection region \textcircled{4}′, the resistor R5′ may correspond to a detection region \textcircled{5}′, and the resistor R6′ may correspond to a detection region \textcircled{6}′.

The resistor R1′ may be connected to the FOP and a sixth branch node N1′, the resistor R2′ may be connected to the sixth branch node N1′ and a seventh branch node N2′, the resistor R3′ may be connected to the seventh branch node N2′ and an eighth branch node N3′, the resistor R4′ may be connected to the eighth branch node N3′ and a ninth branch node N4′, the resistor R5′ may be connected to the ninth branch node N4′ and a tenth branch node N5′, and the resistor R6′ may be connected to the tenth branch node N5′ and the crack detection circuit AP.

To determine an accurate position of a panel crack, the second detection regions RL2 may further include a resistor R7′ connected between the sixth branch node N1′ and the tenth branch node N2′, a resistor R8′ connected between the seventh branch node N2′ and the tenth branch node N3′, a resistor R9′ connected between the eighth branch node N3′ and the tenth branch node N4′, and a resistor R10′ connected between the ninth branch node N4′ and the tenth branch node N5′.

The first detection regions RL1 and the second detection regions RL2 may be axisymmetric with each other. The first detection regions RL1 and the second detection regions RL2 (for example, the detection region \textcircled{1} and the detection region \textcircled{1}′) which are axisymmetric with each other may be designed to have the same resistance value. Also, in order to determine a more accurate position at which a crack occurs, the first detection regions RL1 and the second detection regions RL2 (for example, the detection regions \textcircled{1} and \textcircled{1}′) may be designed to have different resistance values.

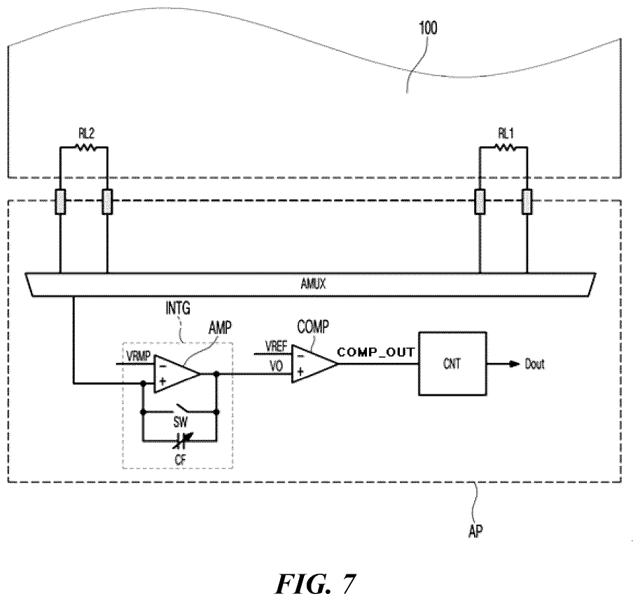

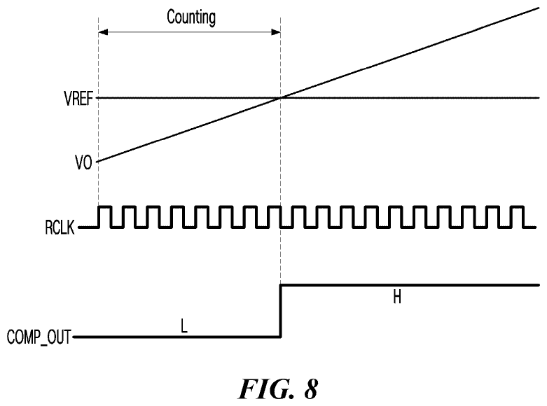

FIG. 7 is a diagram illustrating a configuration of a crack detection circuit AP. FIG. 8 is a driving waveform diagram for describing an operation of the crack detection circuit AP.

The crack detection circuit AP may be embedded in a drive IC, or may be embedded in a host system. A mount position of the crack detection circuit AP is not limited thereto.

Referring to FIG. 7, the crack detection circuit AP may be selectively connected to one of the first detection regions RL1 and the second detection regions RL2 of FIG. 6 and may detect resistance values of the connected detection regions. For example, when a panel crack occurs in the detection region \textcircled{4} as in FIG. 6, a total resistance value Rtotal detected by the crack detection circuit AP may be expressed as the following Equation 1.

Equation 1

Rtotal=R1+R6//(R2+R8)+R6

In Equation 1, R6//(R2+R8) may denote a parallel combined resistance value of R6 and (R2+R8).

Based on such a method, the crack detection circuit AP may detect the first detection regions RL1 and the second detection regions RL2 of FIG. 6 to differently determine, by regions, a position at which a panel crack occurs.

The crack detection circuit AP may include a multiplexer circuit AMUX, an integrator INTG, a comparator COMP, and a counter CNT.

The integrator INTG may be selectively connected to one of the first detection regions RL1 and the second detection regions RL2 through the multiplexer circuit AMUX and may supply a detection driving voltage VRMP to a loop resistance circuit, and then, may perform an integral on a signal fed back from the loop resistance circuit. The integrator INTG may include an amplifier AMP which includes a (−) input terminal, a (+) input terminal, and an output terminal and a reset switch SW a feedback capacitor CF which are connected between the (+) input terminal and the output terminal of the amplifier AMP in parallel. The detection driving voltage VRMP may be supplied to a (−) input terminal of the integrator INTG, and a (+) input terminal of the integrator INTG may be connected to the multiplexer circuit AMUX. An integrator output voltage VO may be output through an output terminal of the integrator INTG.

The comparator COMP may be connected to the output terminal of the integrator INTG. The comparator COMP, as in FIG. 8, may compare the integrator output voltage VO with a reference voltage VREF to generate a comparator output COMP_OUT. A logic level of the comparator output COMP_OUT may be inverted from a low level L to a high level H at a time when the integrator output voltage VO is higher than the reference voltage VREF.

The counter CNT may be connected to an output terminal of the comparator COMP. The counter CNT may count a time taken until a logic level of the comparator output COMP_OUT is inverted, with respect to the reference clock RCLK, and may output a count value as a resistance value Dout of the loop resistance circuit.

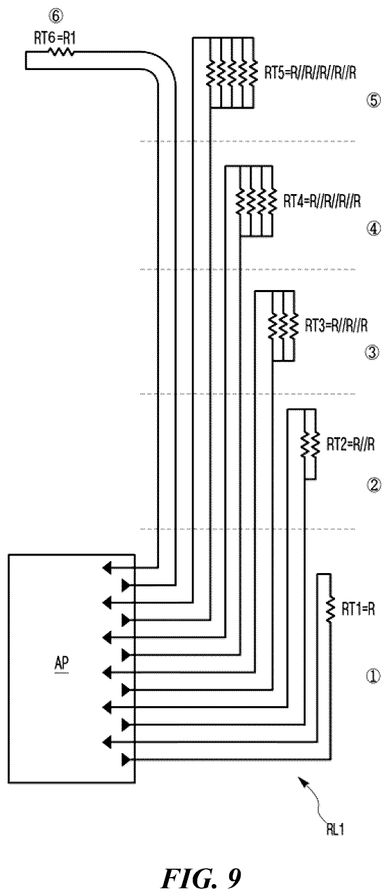

FIG. 9 is a diagram illustrating another configuration of a loop resistance circuit.

Referring to FIG. 9, first detection regions RL1 may include a plurality of first resistance lines and a plurality of first resistors RT1 to RT6, which are electrically disconnected from one another and have different resistance values.

The first detection regions RL1 may correspond to a first edge region of a display panel. The first edge region may include a right edge region and an upper partial edge region of the display panel.

The plurality of first resistors RT1 to RT6 may have different resistance values and may be electrically disconnected from one another through the first resistance lines.

A resistor R may correspond to a detection region \textcircled{1}, a parallel composite resistor R//R may correspond to a detection region \textcircled{2}, a parallel composite resistor R//R//R may correspond to a detection region \textcircled{3}, a parallel composite resistor R//R//R//R may correspond to a detection region \textcircled{4}, a parallel composite resistor R//R//R//R//R may correspond to a detection region \textcircled{5}, and a resistor R1 may correspond to a detection region \textcircled{6}. Here, R//R may be R/2, R//R//R may be R/3, R//R//R//R may be R/4, and R//R//R//R//R may be R/5.

Although not shown in FIG. 9, second detection regions which are axisymmetric with the first detection regions RL1 may be further provided in a second edge region of the display panel. The second edge region may include a left edge region and the other upper edge regions of the display panel.

The second detection regions may include a plurality of second resistance lines and a plurality of second resistors, which are electrically disconnected from one another and have different resistance values.

The plurality of second resistors may have different resistance values and may be electrically disconnected from one another through the second resistance lines.

A resistor R′ may correspond to a detection region \textcircled{1}′ which is axisymmetric with the detection region \textcircled{1}, a parallel composite resistor R′//R′ may correspond to a detection region \textcircled{2}′ which is axisymmetric with the detection region \textcircled{2}, a parallel composite resistor R′//R′//R′ may correspond to a detection region \textcircled{3}′ which is axisymmetric with the detection region \textcircled{3}, a parallel composite resistor R′//R′//R′//R′ may correspond to a detection region \textcircled{4}′ which is axisymmetric with the detection region \textcircled{4}, a parallel composite resistor R′//R′//R′//R′//R′ may correspond to a detection region \textcircled{5}′ which is axisymmetric with the detection region \textcircled{5}, and a resistor R1′ may correspond to a detection region \textcircled{6}′ which is axisymmetric with the detection region \textcircled{6}. Here, R′//R′ may be R′/2, R′//R′//R′ may be R′/3, R′//R′//R′//R′ may be R′/4, and R′//R′//R′//R′//R′ may be R′/5.

First detection regions and second detection regions (for example, the detection regions \textcircled{1} and \textcircled{1}′) may be designed to have the same resistance value, or may be designed to have different resistance values.

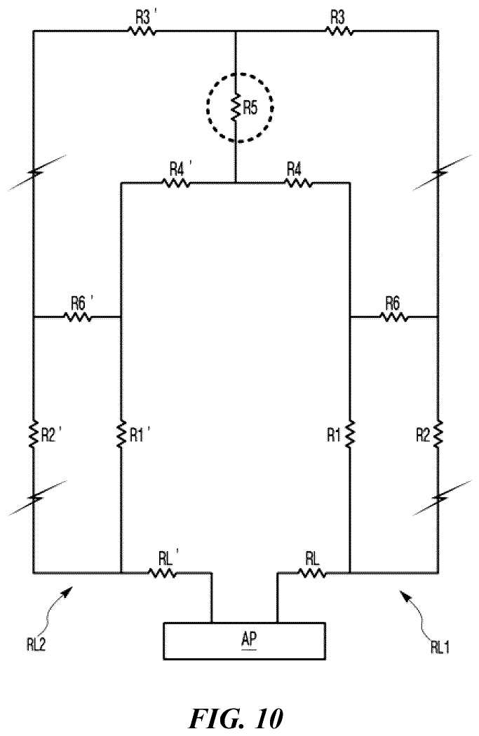

FIG. 10 is a diagram illustrating another configuration of a loop resistance circuit.

Referring to FIG. 10, first detection regions RL1 may include a plurality of first resistance lines and a plurality of first resistors RL and R1 to R4 and R6, which are electrically connected to each other and have different resistance values.

The first detection regions RL1 may correspond to a first edge region of the display panel. The first edge region may include a right edge region and an upper partial edge region of the display panel.

The plurality of first resistors RL and R1 to R4 and R6 may have different resistance values and may be connected to each other through the first resistance lines.

Referring to FIG. 10, second detection regions RL2 which are axisymmetric with the first detection regions RL1 may be further provided in a second edge region of the display panel. The second edge region may include a left edge region and the other upper edge regions of the display panel.

The second detection regions RL2 may include a plurality of second resistance lines and a plurality of second resistors RL′ and R1′ to R4′ and R6′, which are electrically connected to each other and have different resistance values.

The plurality of second resistors RL′ and R1′ to R4′ and R6′ may have different resistance values and may be connected to each other through the second resistance lines.

The plurality of first resistors RL and R1 to R4 and R6 may be electrically connected to the plurality of second resistors RL′ and R1′ to R4′ and R6′ through a third resistor R5, respectively. It should be noted that it can be also expressed as follows: the first detection regions RL1 may include a plurality of first resistance lines and a plurality of first resistors RL and R1 to R6, and the second detection regions RL2 may include a plurality of second resistance lines and a plurality of second resistors RL′ and R1′ to R6′, where R5 can be different from RL and R1 to R4 and R6 as well as RL′ and R1′ to R4′ and R6′, but the same as R5′, which is not limited.

Embodiments of the present disclosure described above will be briefly described below.

A display device according to embodiments of the present disclosure includes a display panel, a loop resistance circuit disposed in an edge region of the display panel, and a crack detection circuit configured to detect a resistance value of the loop resistance circuit. The loop resistance circuit includes first detection regions having different resistance values and second detection regions having different resistance values. The edge region is divided into a first edge region including a right edge region and an upper partial edge region and a second edge region including a left edge region and the other upper edge region. Here, the first detection regions correspond to the first edge region, and the second detection regions correspond to the second edge region.

In the display device according to embodiments of the present disclosure, the first detection regions and the second detection regions may be axisymmetric with each other.

In the display device according to embodiments of the present disclosure, the first detection regions and the second detection regions, which are axisymmetric with each other, may have the same resistance value.

In the display device according to embodiments of the present disclosure, the first detection regions and the second detection regions, which are axisymmetric with each other, may have different resistance values.

In the display device according to embodiments of the present disclosure, the first detection regions may include a plurality of first resistors electrically connected to each other and configured to have different resistance values, the second detection regions may include a plurality of second resistors electrically connected to each other and configured to have different resistance values, and the plurality of first resistors and the plurality of second resistors may be electrically disconnected from one another.

In the display device according to embodiments of the present disclosure, the first detection regions may include a plurality of first resistors electrically disconnected from one another and configured to have different resistance values, and the second detection regions may include a plurality of second resistors electrically disconnected from one another and configured to have different resistance values.

In the display device according to embodiments of the present disclosure, the first detection regions may include a plurality of first resistors electrically connected to each other and configured to have different resistance values, the second detection regions may include a plurality of second resistors electrically connected to each other and configured to have different resistance values, and the plurality of first resistors and the plurality of second resistors may be electrically connected to each other through a third resistor.

In the display device according to embodiments of the present disclosure, the crack detection circuit may include an integrator configured to supply a detection driving voltage to the loop resistance circuit and perform an integral on a signal fed back from the loop resistance circuit, a comparator configured to compare an integrator output voltage with a reference voltage to generate a comparator output, and a counter configured to count a time, taken until a logic level of the comparator output is inverted, and output a count value as a resistance value of the loop resistance circuit.

According to the embodiments of the present disclosure, a resistance value may be designed to be differently detected in each detection region, and based thereon, a position at which a panel crack occurs may be determined in a panel process step or a module process step, thereby enhancing a yield rate of products.

According to the embodiments of the present disclosure, a resistance value may be designed to be differently detected in each detection region, and based thereon, a position at which a panel crack occurs and/or a depth by which the panel crack is formed may be determined, thereby implementing an effective design responding thereto.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel including an edge region;
a loop resistance circuit disposed in the edge region of the display panel; and
a crack detection circuit configured to detect a resistance value of the loop resistance circuit,
wherein the loop resistance circuit includes first detection regions and second detection regions,
wherein the edge region is divided into a first edge region including a right edge region and an upper partial edge region and a second edge region including a left edge region and the other upper partial edge region,
wherein the first detection regions correspond to the first edge region, and
wherein the second detection regions correspond to the second edge region.

2. The display device of claim 1, wherein the first detection regions and the second detection regions are axisymmetric with each other.

3. The display device of claim 2, wherein the first detection regions and the second detection regions, which are axisymmetric with each other, have the same resistance value.

4. The display device of claim 2, wherein the first detection regions and the second detection regions, which are axisymmetric with each other, have different resistance values.

5. The display device of claim 1, wherein the first detection regions comprise a plurality of first resistors electrically connected to each other and configured to have different resistance values,
wherein the second detection regions comprise a plurality of second resistors electrically connected to each other and configured to have different resistance values, and
wherein the plurality of first resistors and the plurality of second resistors are electrically disconnected from one another.

6. The display device of claim 1, wherein the first detection regions comprise a plurality of first resistors electrically disconnected from one another and configured to have different resistance values, and
wherein the second detection regions comprise a plurality of second resistors electrically disconnected from one another and configured to have different resistance values.

7. The display device of claim 1, wherein the first detection regions comprise a plurality of first resistors electrically connected to each other and configured to have different resistance values,
wherein the second detection regions comprise a plurality of second resistors electrically connected to each other and configured to have different resistance values, and
wherein the plurality of first resistors and the plurality of second resistors are electrically connected to each other through a third resistor.

8. The display device of claim 1, wherein the crack detection circuit comprises:
an integrator configured to supply a detection driving voltage to the loop resistance circuit and perform an integral on a signal fed back from the loop resistance circuit;
a comparator configured to compare an integrator output voltage with a reference voltage to generate a comparator output; and
a counter configured to count a time, taken until a logic level of the comparator output is inverted, and output a count value as a resistance value of the loop resistance circuit.

9. The display device of claim 5, wherein the plurality of first resistors is corresponding to different detection regions of the first detection regions, and the plurality of second resistors are corresponding to different detection regions of the second detection regions.

10. The display device of claim 6, wherein the plurality of first resistors is corresponding to different detection regions of the first detection regions, and the plurality of second resistors are corresponding to different detection regions of the second detection regions.
